(19) United States
(12) Patent Application Publication
(10) Pub. No.: US 2022/0329044 A1
(43) Pub. Date: Oct. 13, 2022

(54) VERTICAL-CAVITY SURFACE-EMITTING LASER, MANUFACTURING METHOD, DISTANCE MEASURING DEVICE AND ELECTRONIC DEVICE

(71) Applicant: SILEAD Inc., Shanghai (CN)

(72) Inventors: Shujuan Li, Shanghai (CN); Yongsheng Hou, Shanghai (CN); Zhanqi Xie, Shanghai (CN)

(21) Appl. No.: 17/533,578

(22) Filed: Nov. 23, 2021

(30) Foreign Application Priority Data
Apr. 12, 2021 (CN) 202110390451.0

(51) Int. Cl. H01S 5/042; H01S 5/183

(52) U.S. Cl. CPC H01S 5/04256; H01S 5/04253; H01S 5/18311; H01S 5/18361

(57) ABSTRACT

Provided are a vertical-cavity surface-emitting laser, a manufacturing method, a distance measuring device, and an electronic device. The vertical-cavity surface-emitting laser includes a lower electrode, a substrate, a lower Bragg reflector, an active area, a current limiting layer, an upper Bragg reflector, a protective layer, and an upper electrode. The upper electrode includes at least two sub-electrodes, the at least two sub-electrodes are electrically connected, and the at least two sub-electrodes define one or more light-exiting windows. Each sub-electrode is provided with a corresponding light-exiting window so that the luminous power is increased. Each sub-electrode defines the light-exiting window, and a plurality of sub-electrodes are electrically connected so that the distribution uniformity of the light spots is increased, and the quality of the laser beam is improved.

### CROSS-REFERENCE TO RELATED APPLICATION

This application claims priority to Chinese Patent Application No. 202110390451.0 filed Apr. 12, 2021, the disclosure of which is incorporated herein by reference in its entirety.

### TECHNICAL FIELD

The present disclosure relates to the field of lasers and in particular to, a vertical-cavity surface-emitting laser, a manufacturing method, a distance measuring device, and an electronic device.

### BACKGROUND

A vertical-cavity surface-emitting laser (VCSEL) is a commonly used semiconductor device laser and is widely used in optical storage, optical communications, consumer electronics, 3D perception, Internet of things, autonomous driving and other fields. FIG. 1 is a light-exiting intensity distribution diagram of an existing VCSEL, and an area surrounded by an upper electrode is a light-emitting area 14. As shown in FIG. 1, the position near the upper electrode in the light-emitting area 14 has a relatively high light intensity, that is, the light intensity at the edge of the light-emitting area 14 is relatively high, the light intensity at the center is relatively low, and thus the light spots are uneven. Therefore, there is an urgent need to provide a vertical-cavity surface-emitting laser to solve the preceding problems.

### SUMMARY

The object of the present disclosure is to provide a vertical-cavity surface-emitting laser, a manufacturing method, a distance measuring device, and an electronic device.

In one aspect, a vertical-cavity surface-emitting laser is provided. The vertical-cavity surface-emitting laser includes a lower electrode, a substrate, a lower Bragg reflector, an active area, a current limiting layer, an upper Bragg reflector, a protective layer, and an upper electrode. The upper electrode includes at least two sub-electrodes, the at least two sub-electrodes are electrically connected, and the at least two sub-electrodes define one or more light-exiting windows.

In another aspect, a manufacturing method of a vertical-cavity surface-emitting laser is provided. The manufacturing method includes the steps described below. A lower Bragg reflector, an active area, an oxidizable material layer, and an upper Bragg reflector are sequentially formed on a substrate. Openings that penetrate the upper Bragg reflector and the oxidizable material layer are formed. The oxidizable material layer is laterally oxidized so that a current limiting layer is formed. A protective layer covering the active area, the upper Bragg reflector, and sidewalls of the openings is formed. The protective layer above the upper Bragg reflector is removed. An electrode material is deposited such that the electrode material covers the upper Bragg reflector and the protective layer and fills the openings. An electrode material above the upper Bragg reflector is patterned so that an upper electrode is formed, where the upper electrode includes at least two sub-electrodes, the at least two sub-electrodes are electrically connected, and the at least two sub-electrodes define one or more light-exiting windows.

In yet another aspect, a distance measuring device is provided. The distance measuring device includes a transmitting end and a receiving end, where the transmitting end includes at least one vertical-cavity surface-emitting laser as described in any one of the above, and the receiving end is configured to receive a light that is emitted by the vertical-cavity surface-emitting laser to a surface of a target object and reflected.

In yet another aspect, an electronic device is provided. The electronic device includes the preceding distance measuring device.

### BRIEF DESCRIPTION OF DRAWINGS

FIG. 1 is a light-exiting intensity distribution diagram of an existing vertical-cavity surface-emitting laser;

FIG. 2 is a space diagram of a vertical-cavity surface-emitting laser according to an embodiment of the present disclosure;

FIG. 3 is a sectional diagram of the vertical-cavity surface-emitting laser according to an embodiment of the present disclosure;

FIG. 4 is a top diagram of the vertical-cavity surface-emitting laser in FIG. 3;

FIG. 5 is a sectional diagram of another vertical-cavity surface-emitting laser according to an embodiment of the present disclosure;

FIG. 6 is a top diagram of the vertical-cavity surface-emitting laser in FIG. 5;

FIG. 7 is a top diagram of another upper electrode of the vertical-cavity surface-emitting laser according to an embodiment of the present disclosure;

FIG. 8 is a top diagram of another upper electrode of the vertical-cavity surface-emitting laser according to an embodiment of the present disclosure;

FIG. 9 is a top diagram of another upper electrode of the vertical-cavity surface-emitting laser according to an embodiment of the present disclosure;

FIG. 10 is a top diagram of another upper electrode of the vertical-cavity surface-emitting laser according to an embodiment of the present disclosure;

FIG. 11 is a top diagram of another upper electrode of the vertical-cavity surface-emitting laser according to an embodiment of the present disclosure;

FIG. 12 is a flowchart of main steps of a manufacturing method of a vertical-cavity surface-emitting laser according to an embodiment of the present disclosure; and

FIGS. 13 to 19 are process diagrams of the manufacturing method of a vertical-cavity surface-emitting laser according to an embodiment of the present disclosure.

### REFERENCE LIST IN DRAWINGS

1 lower electrode
2 substrate
3 lower Bragg reflector
4 active area
5 current limiting layer
6 upper Bragg reflector
7 protective layer
8 upper electrode
9 current window
10 light-exiting window
11 opening
12 groove
13 mesa
14 light-emitting area
15 upper electrode pad
16 connection electrode

### DETAILED DESCRIPTION

To make solved problems, adopted technical solutions, and achieved effects of the present disclosure clearer, the technical solutions of the present disclosure are further described in detail in conjunction with drawings. Apparently, the embodiments described below are part, not all, of embodiments of the present disclosure. Based on embodiments of the present disclosure, all other embodiments obtained by those skilled in the art are within the scope of the present disclosure on the premise that no creative work is done.

In the description of the present disclosure, unless otherwise expressly specified and limited, the term “connected” is to be construed in a broad sense, for example, as permanently connected, detachably connected, or integrated; mechanically connected or electrically connected; directly connected to each other or indirectly connected to each other via an intermediary; or internally connected or interactional between two components. For those of ordinary skill in the art, specific meanings of the preceding term in the present disclosure may be construed based on specific situations.

In the present disclosure, unless otherwise expressly specified and limited, when a first feature is described as “above” or “below” a second feature, the first feature and the second feature may be in direct contact or be in contact via another feature between the two features. Moreover, when the first feature is described as “on”, “above”, or “over” the second feature, the first feature is right on, above, or over the second feature or the first feature is obliquely on, above, or over the second feature, or the first feature is simply at a higher level than the second feature. When the first feature is described as “under”, “below”, or “underneath” the second feature, the first feature is right under, below, or underneath the second feature or the first feature is obliquely under, below, or underneath the second feature, or the first feature is simply at a lower level than the second feature.

As shown in FIGS. 2, 3, and 4, this embodiment provides a vertical-cavity surface-emitting laser. The vertical-cavity surface-emitting laser includes a lower electrode 1, a substrate 2, a lower Bragg reflector 3, an active area 4, a current limiting layer 5, an upper Bragg reflector 6, a protective layer 7, and an upper electrode 8.

The substrate 2 is, for example, a silicon substrate, a sapphire substrate, an indium phosphide (InP) substrate, a gallium nitride (GaN) substrate, a gallium arsenide (GaAs) substrate, an indium gallium nitride (InGaN) substrate, a sapphire substrate, a silicon carbide (SiC) substrate, or the like. The lower Bragg reflector 3, the active area 4, the current limiting layer 5, and the upper Bragg reflector 6 are disposed on the substrate 2 so as to form the mesas 13, and each mesa 13 corresponds to one laser unit. In some embodiments, a buffer layer is disposed between the lower Bragg reflector 3 and the substrate 2 so that material matching is improved and defects are reduced.

Each of the lower Bragg reflector 3 and the upper Bragg reflector 6 is a multilayer structure and includes two kinds of films alternately arranged. The two kinds of films have different refractive indices. In an embodiment, the difference in the refractive indices of the two kinds of films forming the Bragg reflector is greater than 0.5. For example, each of the lower Bragg reflector 3 and the upper Bragg reflector 6 includes a TiO₂ layer and a SiO₂ layer that are alternately grown. For another example, the substrate 2 is a GaAs substrate, and each of the lower Bragg reflector 3 and the upper Bragg reflector 6 includes an AlAs layer and a GaAs layer that are alternately grown.

The active area 4 is a light generating area, which is disposed between the lower Bragg reflector 3 and the upper Bragg reflector 6. A buffer layer may also be disposed between the active area 4 and the lower Bragg reflector 3. The material of the active area 4 is, for example, InGaAlAs, InGaAlP, InGaAsN, GaInAs, and GaAlAs. In some embodiments, the active area 4 is a quantum well structure, the quantum well structure includes at least one potential well layer and at least two potential barrier layers, and the at least one potential well layer is disposed between the at least two potential barrier layers. In an embodiment, the energy gap difference between each potential barrier layer and each potential well layer is 0.5 eV to 0.7 eV. In an embodiment, the potential barrier layer is InGaAlAs, and the potential well layer is InGaAs. In another embodiment, the potential barrier layer is InAsP, and the potential well layer is InGaAsP. In yet another embodiment, the potential barrier layer is InGa, InAs, and (AlAs)₃, and the potential well layer is InGa, (InAs)₂, and (AlAs)₂.

The current limiting layer 5 is disposed between the active area 4 and the upper Bragg reflector 6. The current limiting layer 5 is configured to improve the efficiency of current injection into the active area 4 and reduce a threshold current. The current limiting layer 5 includes a current limiting area and a current injection area, and the current injection area is also referred to as a current window 9. The current limiting layer 5 includes, for example, Al elements, and the current limiting area is formed by laterally oxidizing an Al-rich material.

The lower electrode 1 is, for example, an n-electrode, and the upper electrode 8 is, for example, a p-electrode. Each of the lower electrode 1 and the upper electrode 8 is formed on a respective side of two sides of the active area 4. In the vertical-cavity surface-emitting laser shown in FIG. 2, the active area 4 is disposed on one side of the substrate 2, and the lower electrode 1 is formed on the other side of the substrate 2. In other embodiments, the active area 4 and the lower electrode 1 are disposed on the same side of the substrate 2. The lower electrode 1 and the upper electrode 8 are made of metal materials, such as one or more selected from Cr, Al, Ti, Au, Ni, Pt, Ag, and Indium Tin Oxide (ITO). In some embodiments, the lower electrode 1 and the upper electrode 8 are a stack of multiple layers of metal.

A voltage is applied to the lower electrode 1 and the upper electrode 8 so that a current injected into the active area 4 is formed. The active area 4 generates the laser. The laser is reflected between the upper Bragg reflector 6 and the lower Bragg reflector 3 for multiple times and is emitted from a light-exiting window 10.

The upper electrode 8 is disposed above the upper Bragg reflector 6 and extends along a sidewall of the mesa 13 so as to connect an upper electrode pad 15. The upper electrode 8 includes multiple sub-electrodes, and the multiple sub-electrodes are electrically connected through connection electrodes. One or more light-exiting windows 10 are defined by the multiple sub-electrodes so that better light-exiting intensity uniformity of all the light-exiting windows 10 is ensured. The outermost sub-electrode is connected to the upper electrode pad 15, and the upper electrode pad 15 is disposed on the protective layer 7 between the mesas.

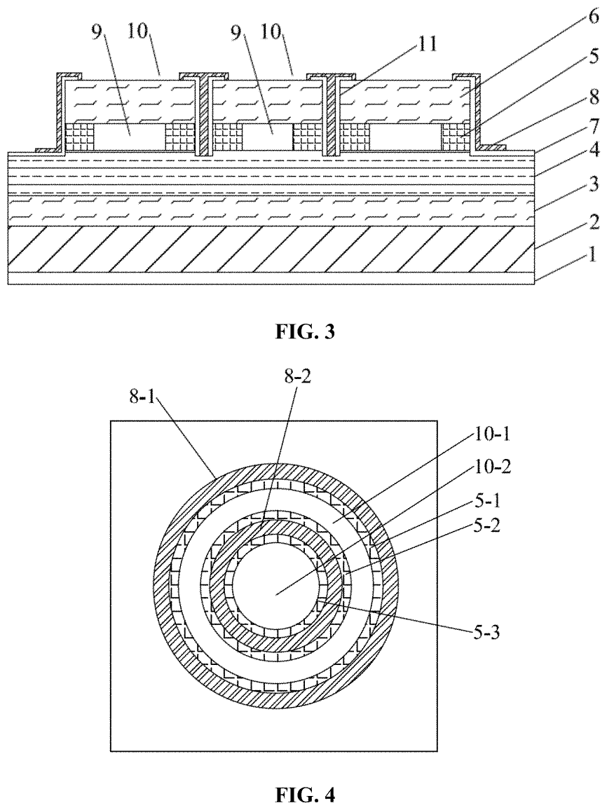

As shown in FIGS. 2 to 4, the upper electrode 8 includes at least two sub-electrodes, and the at least two sub-electrodes are electrically connected. The at least two sub-electrodes define one or more light-exiting windows 10. In the embodiment shown in FIGS. 2 to 4, the upper electrode 8 includes a first sub-electrode 8-1 and a second sub-electrode 8-2, and the first sub-electrode 8-1 and the second sub-electrode 8-2 define a first light-exiting window 10-1 and a second light-exiting window 10-2. In an embodiment, the first light-exiting window 10-1 and the second light-exiting window 10-2 are coaxially arranged. The current limiting layer 5 includes one or more current windows 9. The current is allowed to pass through each current window 9 and is not allowed to pass through other areas of the current limiting layer 5. In the embodiment shown in FIGS. 2 to 4, the current limiting layer 5 includes two current windows 9, and two light-exiting windows 10 are in one-to-one correspondence with two current windows 9. Each light-exiting window 10 and the corresponding current window 9 have substantially the same shape, and each current window 9 is disposed under the corresponding light-exiting window 10. In the embodiment shown in FIG. 3, the sub-electrode includes a part that penetrates the upper Bragg reflector 6. In some embodiments, the connection electrodes that achieve the electrical connection between the sub-electrodes also include a part that penetrates the upper Bragg reflector 6. In an embodiment, the upper Bragg reflector 6 is provided with openings 11, the openings 11 penetrate the upper Bragg reflector 6 and the current limiting layer 5, and the openings 11 are filled with an electrode material so that a part of a corresponding sub-electrode that penetrates the upper Bragg reflector 6 is formed. FIG. 4 is a top diagram of the vertical-cavity surface-emitting laser. As shown in FIGS. 3 and 4, the openings 11 are ring-shaped grooves, and the second sub-electrode 8-2 includes a part located above the mesa 13 and a part located in a respective opening 11. The protective layer 7 covers the sidewall of the mesa 13 and the inner walls of the openings 11. The first electrode 8-1 includes a part located above the mesa 13 and a part along the sidewall of the mesa 13.

In other embodiments, the openings 11 are filled with a non-electrode material, and the second sub-electrode 8-2 is located above the upper Bragg reflector 6, excluding the part that penetrates the upper Bragg reflector 6.

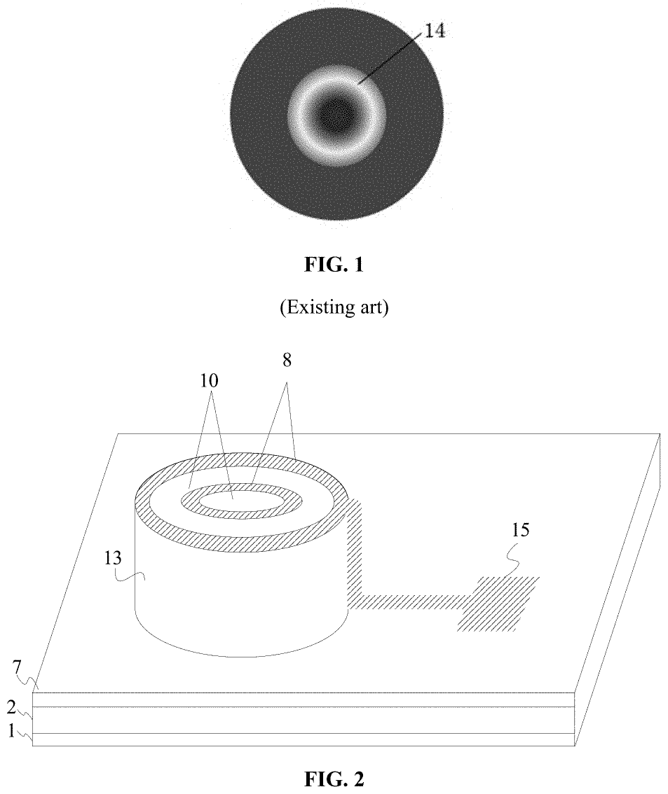

As shown in FIGS. 2 to 4, the first sub-electrode 8-1 and the second sub-electrode 8-2 of the upper electrode 8 are both ring-shaped. The first sub-electrode 8-1 and the second sub-electrode 8-2 may also be square ring-shaped and circular ring-shaped. The first sub-electrode 8-1 and the second sub-electrode 8-2 define the first light-exiting window 10-1, and the second sub-electrode 8-2 defines the second light-exiting window 10-2. The first light-exiting window 10-1 is, for example, ring-shaped, and the second light-exiting window 10-2 is, for example, circular. As shown in FIGS. 3 and 4, the first light-exiting window 10-1 is disposed between the first sub-electrode 8-1 and the second sub-electrode 8-2, two sides are provided with upper electrodes, and the light-exiting intensity uniformity of the first light-exiting window 10-1 is better than the light-exiting intensity uniformity of the light-exiting window 10 defined by the upper electrode 8 shown in FIG. 1. The area of the second light-exiting window 10-2 is relatively small, and the distance between the center of the second light-exiting window 10-2 and the upper electrode 8 is less than the distance between the center of the light-exiting window 10 and the upper electrode 8 shown in FIG. 1. Therefore, a relatively high light-exiting intensity is ensured, and the light-exiting intensity uniformity of the second light-exiting window 10-2 is also better than the light-exiting intensity uniformity of the corresponding position of the light-exiting window 10 shown in FIG. 1.

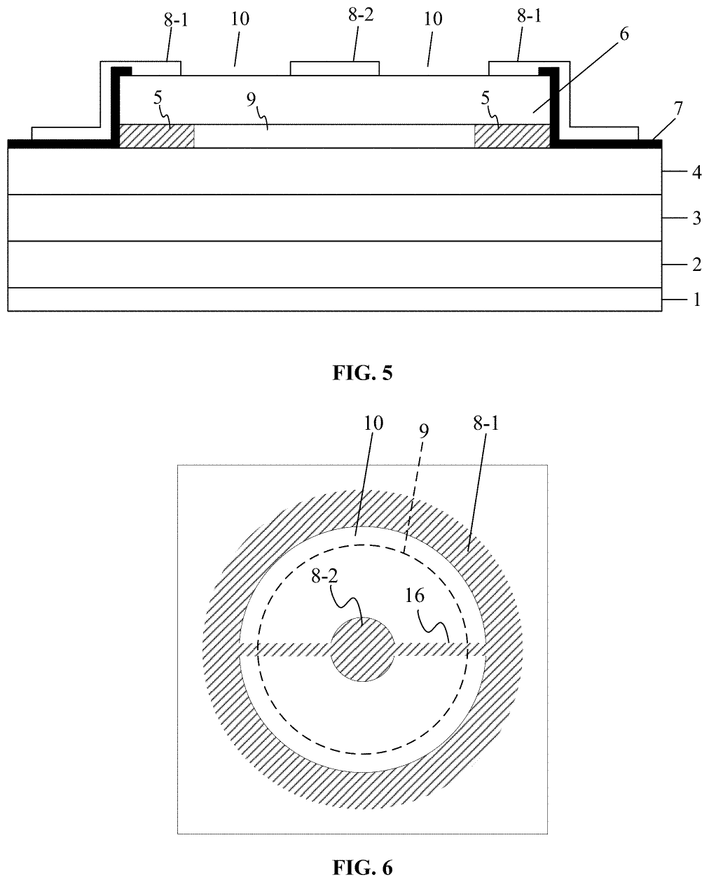

FIG. 5 is a sectional diagram of another vertical-cavity surface-emitting laser. FIG. 6 is a top diagram of the vertical-cavity surface-emitting laser in FIG. 5. In the embodiment shown in FIGS. 5 and 6, the upper electrode 8 includes a first sub-electrode 8-1 and a second sub-electrode 8-2. The first sub-electrode 8-1 is ring-shaped, and the second sub-electrode 8-2 is in a non-annular shape such as a circle and a square. The first sub-electrode 8-1 and the second sub-electrode 8-2 are connected through the connection electrodes 16. The first sub-electrode 8-1 and the second sub-electrode 8-2 define one light-exiting window 10, and the light-exiting window 10 is located between the first sub-electrode 8-1 and the second sub-electrode 8-2. In this embodiment, two connection electrodes 16 are provided, and the two connection electrodes 16 divide the light-exiting window 10 into two parts. The first sub-electrode 8-1, the second sub-electrode 8-2, and the connection electrodes 16 are disposed above the upper Bragg reflector 6, excluding the part that penetrates the upper Bragg reflector 6. The current limiting layer 5 includes one current window 9. The range of the current window 9 is shown by a dotted line in FIG. 6. The second sub-electrode 8-2 is disposed near the center of the light-exiting window 10 so that the light-exiting intensity at the center of the light-exiting window 10 is increased, and thus the light-exiting intensity uniformity of the light-exiting window 10 is improved. In an embodiment, the second sub-electrode 8-2 is a transparent electrode, and the material of the transparent electrode is, for example, ITO, AZO, or FTO. The second sub-electrode 8-2 is configured as a transparent electrode so that the area of the light-exiting window 10 is increased.

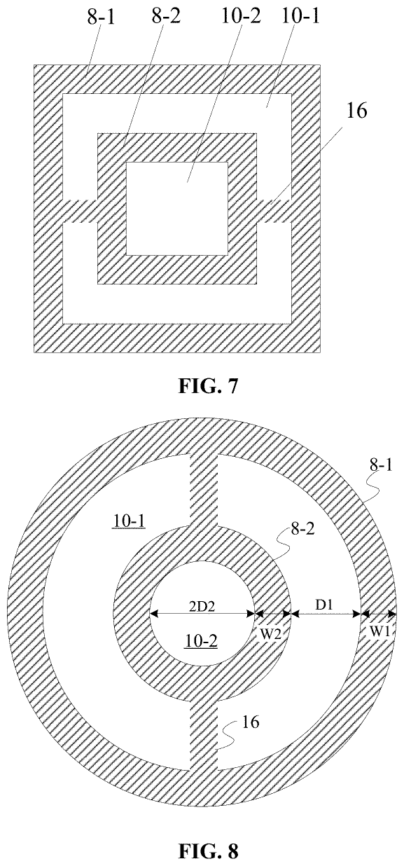

FIG. 7 is a top diagram of another upper electrode of the vertical-cavity surface-emitting laser. In the embodiment shown in FIG. 7, the upper electrode 8 includes a first sub-electrode 8-1 and a second sub-electrode 8-2, and the first sub-electrode 8-1 and the second sub-electrode 8-2 are electrically connected through the connection electrodes 16. Each of the first sub-electrode 8-1 and the second sub-electrode 8-2 is square ring-shaped. The first light-exiting window 10-1 between the first sub-electrode 8-1 and the second sub-electrode 8-2 is also square ring-shaped. The second light-exiting window 10-2 is rectangular and surrounded by the second sub-electrode 8-2. In the embodiment shown in FIG. 7, two connection electrodes 16 are provided, the two connection electrodes 16 divide the first light-exiting window 10-1 into two parts, and the two parts are symmetrically arranged. In some embodiments, the area of the first light-exiting window 10-1 is greater than or equal to twice the area of the second light-exiting window 10-2.

FIG. 8 is a top diagram of another upper electrode of the vertical-cavity surface-emitting laser. The upper electrode 8 includes a first sub-electrode 8-1 and a second sub-electrode 8-2, and the first sub-electrode 8-1 and the second sub-electrode 8-2 are electrically connected through the connection electrodes 16. Each of the first sub-electrode 8-1 and the second sub-electrode 8-2 is circular ring-shaped. The width W1 of the first sub-electrode 8-1 may be equal to or may not be equal to the width W2 of the second sub-electrode 8-2. The first light-exiting window 10-1 is also circular ring-shaped and has a width D1. The second light-exiting window 10-2 is circular, and the diameter of the second light-exiting window 10-2 is 2*D2.

In some embodiments, the width W1 of the first sub-electrode 8-1 and the width W2 of the second sub-electrode 8-2 are the same, and in an embodiment, each of the width D1 of the first light-exiting window 10-1 and the width D2 of the second light-exiting window 10-2 is twice the width W1 of the first sub-electrode 8-1. With this arrangement, the light-exiting intensity uniformity of the first light-exiting window 10-1 and the second light-exiting window 10-2 is relatively high.

In some embodiments, the width W1 of the first sub-electrode 8-1 is different from the width W2 of the second sub-electrode 8-2, and in an embodiment, the width D1 of the first light-exiting window 10-1 is three times the width W1 of the first sub-electrode 8-1, and the width D2 of the second light-exiting window 10-2 is twice the width W2 of the second sub-electrode 8-2. With this arrangement, the light-exiting intensity uniformity of the first light-exiting window 10-1 and the second light-exiting window 10-2 is relatively high.

In some embodiments, the area of the first light-exiting window 10-1 is greater than or equal to twice the area of the second light-exiting window 10-2.

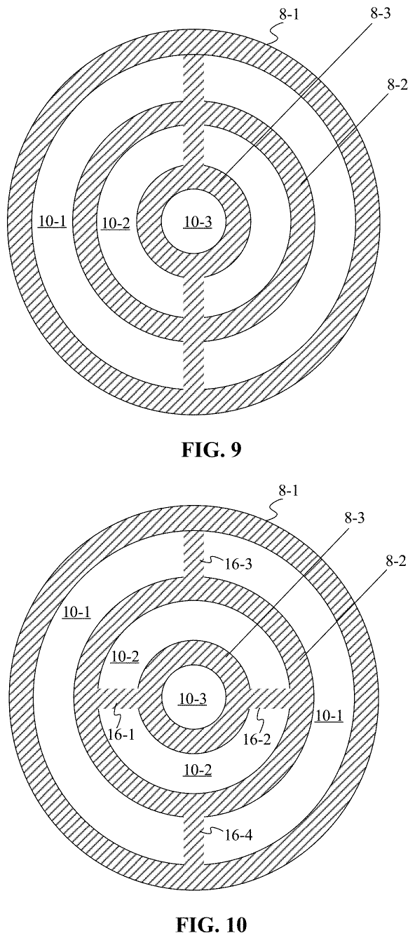

FIG. 9 is a top diagram of another upper electrode of the vertical-cavity surface-emitting laser. The upper electrode 8 includes a first sub-electrode 8-1, a second sub-electrode 8-2, and a third sub-electrode 8-3. The first sub-electrode 8-1, the second sub-electrode 8-2, and the third sub-electrode 8-3 are connected through the connection electrodes 16. Each of the first sub-electrode 8-1, the second sub-electrode 8-2, and the third sub-electrode 8-3 is circular ring-shaped. Three light-exiting windows 10 are provided and the three light-exiting windows 10 are a first light-exiting window 10-1 disposed between the first sub-electrode 8-1 and the second sub-electrode 8-2, a second light-exiting window 10-2 disposed between the second sub-electrode 8-2 and the third sub-electrode 8-3, and a third light-exiting window 10-3 surrounded by the third sub-electrode 8-3, respectively. The first light-exiting window 10-1 and the second light-exiting window 10-2 are also circular ring-shaped. The third light-exiting window 10-3 is circular. In some embodiments, the area of the first light-exiting window 10-1 is greater than or equal to twice the area of the second light-exiting window 10-2, and the area of the second light-exiting window 10-2 is greater than or equal to twice the area of the third light-exiting window 10-3. FIG. 10 is a top diagram of another upper electrode of the vertical-cavity surface-emitting laser. The upper electrode 8 includes a first sub-electrode 8-1, a second sub-electrode 8-2, and a third sub-electrode 8-3. The first sub-electrode 8-1 and the second sub-electrode 8-2 are electrically connected through a connection electrode 16-3 and a connection electrode 16-4, and the second sub-electrode 8-2 and the third sub-electrode 8-3 are electrically connected through a connection electrode 16-1 and a connection electrode 16-2. The connection electrode 16-1 and the connection electrode 16-2 are arranged on a first straight line. The connection electrode 16-3 and the connection electrode 16-4 are arranged on a second straight line. The first straight line and the second straight line intersect. The first light-exiting window 10-1 is divided into two parts by the connection electrode 16-3 and the connection electrode 16-4. The second light-exiting window 10-2 is divided into two parts by the connection electrode 16-1 and the connection electrode 16-2.

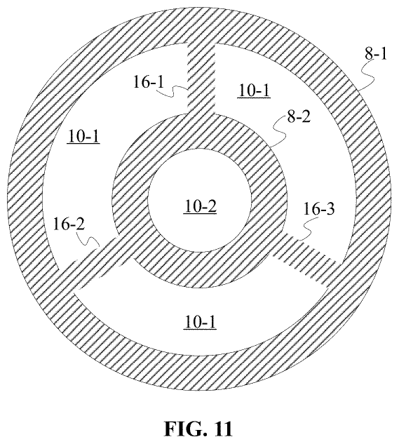

FIG. 11 is a top diagram of another upper electrode of the vertical-cavity surface-emitting laser. The upper electrode 8 includes a first sub-electrode 8-1 and a second sub-electrode 8-2, and the first sub-electrode 8-1 and the second sub-electrode 8-2 are electrically connected through three connection electrodes 16-1, 16-2, and 16-3. The angle between every two of the three connection electrodes is about 60 degrees. The first light-exiting window 10-1 is divided into three parts by the connecting electrodes 16-1, 16-2, and 16-3.

FIGS. 6 to 11 list various manners of disposing the upper electrode, but the upper electrode of the present application is not limited to the manners shown in the figures. If not in collision, the manners of disposing the sub-electrodes and the manners of disposing the connection electrodes in FIGS. 6 to 11 may be combined with each other.

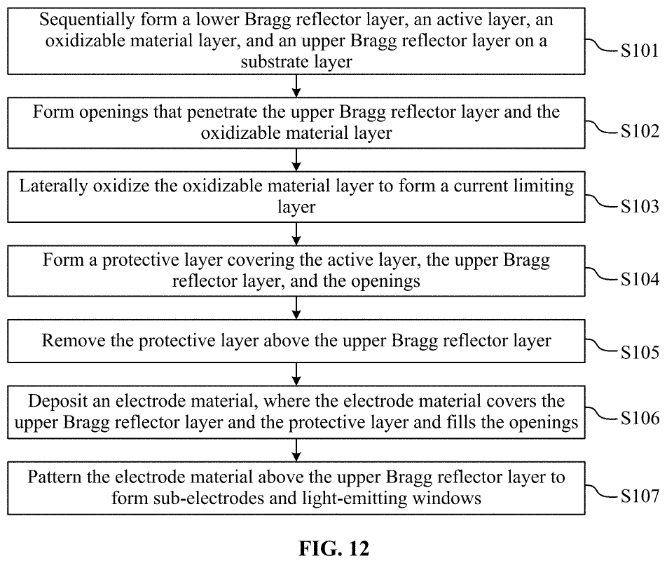

As shown in FIG. 12, this embodiment provides a manufacturing method of a vertical-cavity surface-emitting laser. The manufacturing method includes the steps described below.

In step S101, a lower Bragg reflector 3, an active area 4, an oxidizable material layer, and an upper Bragg reflector 6 are sequentially formed on a substrate 2.

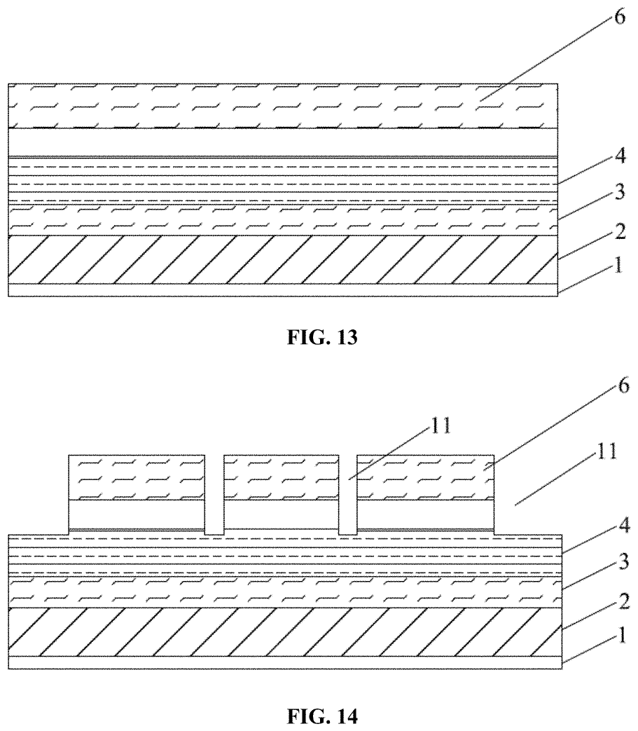

In an embodiment, as shown in FIG. 13, the lower Bragg reflector 3, the active area 4, the oxidizable material layer, and an upper Bragg reflector 6 are sequentially formed on one side of the substrate 2 from bottom to top, and the other side of the substrate 2 is formed with a lower electrode 1. In the case where the substrate 2 is a gallium arsenide (GaAs) substrate is used as an example, the lower Bragg reflector 3, the active area 4, the oxidizable material layer, and the upper Bragg reflector 6 are grown on the gallium arsenide substrate through an epitaxial process. Each of the lower Bragg reflector 3 and the upper Bragg reflector 6 includes, for example, an AlAs film and a GaAs film that are alternately arranged.

In step S102, mesas 13 are formed, and openings 11 that penetrate the upper Bragg reflector 6 and the oxidizable material layer are formed.

For example, the mesas 13 and the openings 11 are formed by etching. Each mesa 13 corresponds to one laser unit, and an array of multiple mesas 13 forms a laser array. When viewed from a plan view, the mesa 13 is, for example, square or circular. As shown in FIGS. 13 and 14, when the mesas 13 are formed, the upper Bragg reflector 6 is provided with the openings 11, and the openings 11 penetrate the upper Bragg reflector 6 and a current limiting layer 5. While the openings 11 are formed, grooves 12 are formed.

In step S103, the oxidizable material layer is laterally oxidized so that a current limiting layer 5 is formed.

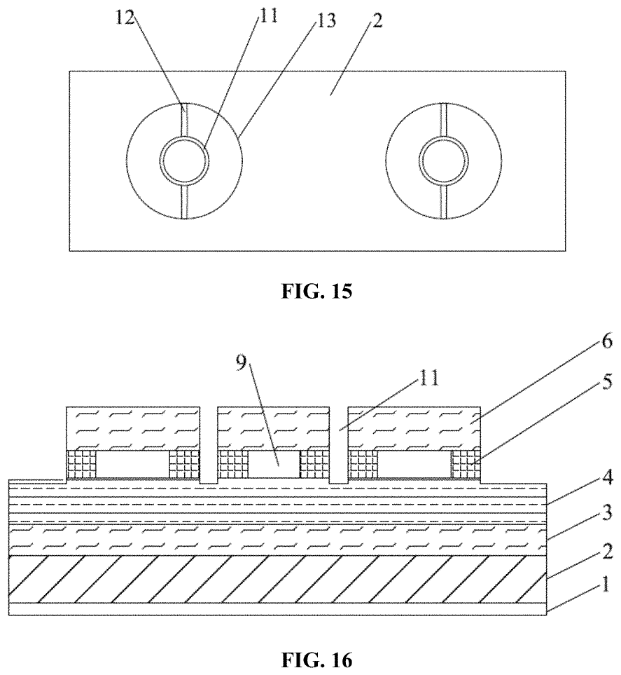

The material of the oxidizable material layer is conductive and does not conduct electricity after being oxidized. The material of the oxidizable material layer is, for example, AlAs. In an embodiment, as shown in FIG. 15, the current limiting layer 5 is formed through lateral oxidation. The oxidized part of the oxidizable material layer is a current limiting area, and the unoxidized part is a current injection area (that is, a current window 9).

Further, the oxidizable material layer is laterally oxidized through wet oxidation.

In step S104, as shown in FIG. 16, a protective layer 7 covering an upper surface of the mesas 13 (that is, an upper surface of the upper Bragg reflector 6), sidewalls of the mesas 13, and the inner walls of the openings 11 are formed.

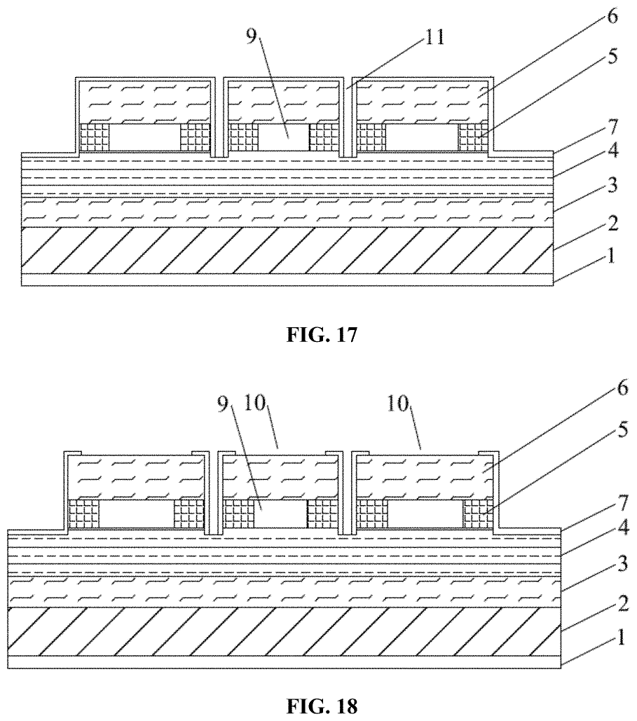

In step S105, as shown in FIG. 17, the protective layer 7 above the upper Bragg reflector 6 is removed. In an embodiment, the protective layer 7 above the upper Bragg reflector 6 is removed, and the upper Bragg reflector 6 is exposed in an area where a light-exiting window 10 is formed.

In step S106, as shown in FIG. 18, an electrode material for forming the upper electrode 8 is deposited, where the electrode material covers the upper Bragg reflector 6 and the protective layer 7 and fills the openings 11.

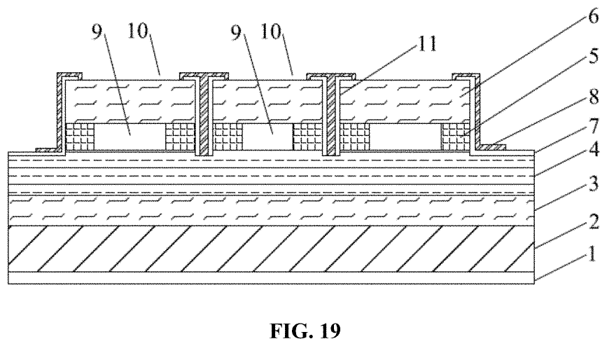

In step S107, with continued reference to FIG. 19, the electrode material above the upper Bragg reflector 6 is patterned to form sub-electrodes and light-exiting windows 10.

This embodiment provides a distance measuring device. The distance measuring device includes a transmitting end and a receiving end, where the transmitting end includes at least one vertical-cavity surface-emitting laser as described in this embodiment, and the receiving end is configured to receive a light that is emitted by the vertical-cavity surface-emitting laser to a surface of a target object and reflected by the surface of the target object. The distance measuring device using the vertical-cavity surface-emitting laser provided in embodiment one has high accuracy of distance measurement.

Further, the receiving end includes a light sensor. In an embodiment, the light sensor is a broad-spectrum light sensor, and the broad-spectrum light sensor may receive laser emitted by the vertical-cavity surface-emitting laser. The receiving end and the transmitting end may be installed on the same substrate or connection board.

This embodiment further provides an electronic device. The electronic device includes the preceding distance measuring device. The electronic device may be a mobile phone, a computer, a tablet, and the like, and may also be an electronic device used in automobiles, aircraft, household appliances, and the like.

Apparently, the preceding embodiments of the present disclosure are merely illustrative of the present disclosure and are not intended to limit embodiments of the present disclosure. For those of ordinary skill in the art, alterations or modifications in other different forms can be made based on the above description. Implementations of the present disclosure cannot be and do not need to be all exhausted herein. Any modification, equivalent substitution, and improvement within the spirit and principle of the present disclosure fall within the scope of the claims of the present disclosure.

What is claimed is:

1. A vertical-cavity surface-emitting laser, comprising a lower electrode, a substrate, a lower Bragg reflector, an active area, a current limiting layer, an upper Bragg reflector, a protective layer, and an upper electrode, wherein the upper electrode comprises at least two sub-electrodes, the at least two sub-electrodes are electrically connected, and the at least two sub-electrodes define one or more light-exiting windows.

2. The vertical-cavity surface-emitting laser of claim 1, wherein at least two light-exiting windows are provided, and the at least two light-exiting windows are coaxially arranged.

3. The vertical-cavity surface-emitting laser of claim 2, wherein the current limiting layer comprises at least two current windows, and the at least two current windows are in one-to-one correspondence with the at least two light-exiting windows.

4. The vertical-cavity surface-emitting laser of claim 1, wherein the current limiting layer comprises one or more current windows.

5. The vertical-cavity surface-emitting laser of claim 1, wherein the at least two sub-electrodes are disposed above the upper Bragg reflector.

6. The vertical-cavity surface-emitting laser of claim 5, wherein the at least two sub-electrodes penetrate the upper Bragg reflector.

7. The vertical-cavity surface-emitting laser of claim 1, wherein two sub-electrodes are provided and the two sub-electrodes are a first sub-electrode and a second sub-electrode, one light-exiting window is provided, and the light-exiting window is disposed between the first sub-electrode and the second sub-electrode.

8. The vertical-cavity surface-emitting laser of claim 7, wherein the light-exiting window surrounds the second sub-electrode.

9. The vertical-cavity surface-emitting laser of claim 8, wherein the second sub-electrode is a transparent electrode.

10. The vertical-cavity surface-emitting laser of claim 1, wherein the at least two sub-electrodes are electrically connected through connection electrodes.

11. The vertical-cavity surface-emitting laser of claim 1, wherein two sub-electrodes are provided and the two sub-electrodes are a first sub-electrode and a second sub-electrode, and two light-exiting windows are provided and the two light-exiting windows are a first light-exiting window disposed between the first sub-electrode and the second sub-electrode and a second light-exiting window surrounded by the second sub-electrode.

12. The vertical-cavity surface-emitting laser of claim 11, wherein an area of the first light-exiting window is greater than or equal to twice an area of the second light-exiting window.

13. A manufacturing method of a vertical-cavity surface-emitting laser, comprising:
sequentially forming a lower Bragg reflector, an active area, an oxidizable material layer, and an upper Bragg reflector on a substrate;
forming openings that penetrate the upper Bragg reflector and the oxidizable material layer;
laterally oxidizing the oxidizable material layer to form a current limiting layer;
forming a protective layer covering the active area, the upper Bragg reflector, and sidewalls of the openings;
removing the protective layer above the upper Bragg reflector;
depositing an electrode material, wherein the electrode material covers the upper Bragg reflector and the protective layer and fills the openings; and
patterning an electrode material above the upper Bragg reflector to form an upper electrode, wherein the upper electrode comprises at least two sub-electrodes, the at least two sub-electrodes are electrically connected, and the at least two sub-electrodes define one or more light-exiting windows.

14. The vertical-cavity surface-emitting laser of claim 13, wherein the oxidizable material layer is laterally oxidized through wet oxidation.

15. A distance measuring device, comprising a transmitting end and a receiving end, wherein the transmitting end comprises at least one vertical-cavity surface-emitting laser, the receiving end is configured to receive light that is emitted by the vertical-cavity surface-emitting laser to a surface of a target object and reflected by the surface of a target object, and the vertical-cavity surface-emitting laser comprises a lower electrode, a substrate, a lower Bragg reflector, an active area, a current limiting layer, an upper Bragg reflector, a protective layer, and an upper electrode, wherein the upper electrode comprises at least two sub-electrodes, the at least two sub-electrodes are electrically connected, and the at least two sub-electrodes define one or more light-exiting windows.

16. An electronic device, comprising the distance measuring device of claim 15.
